(19) United States
(12) Patent Application Publication
(10) Pub. No.: US 2005/0254668 A1
(43) Pub. Date: Nov. 17, 2005

(54) Loudspeaker arrangement

(76) Inventor: Walter Gentele, Abenberg (DE)

Correspondence Address: QUARLES & BRADY LLP, 411 E. WISCONSIN AVENUE, SUITE 2040, MILWAUKEE, WI, 53202-4497, US

(21) Appl. No.: 10/524,307

(22) PCT Filed: Aug. 12, 2003
(86) PCT No.: PCT/EP03/08922

§ 371 Date: Feb. 7, 2005

(30) Foreign Application Priority Data
Aug. 16, 2002 (DE) 10237623.9

(51) Int. Cl. H03G 5/00; H04R 1/02

(52) U.S. Cl. 381/99; 381/335

(57) ABSTRACT

The invention relates to a loudspeaker arrangement inside a device for playing back stereophonic audio signals. The inventive loudspeaker arrangement consists of a housing located inside the device, a loudspeaker for bass signals, and of loudspeakers for mid-range and treble signals. Crossover networks divide the stereophonic audio signals for playback by the loudspeakers into bass signals, mid-range signals and treble signals. The crossover network have a crossover frequency that is higher than the cut-off frequency of the loudspeaker for bass signals.

The present invention concerns a loudspeaker arrangement in a device for playback of stereophonic audio signals.

A loudspeaker arrangement for playback of stereophonic audio signals that is integrated in a device is known. The size of the housing used to accommodate the loudspeaker arrangement is stipulated by the size required by the device.

The problem, that due to the restricted dimensions of the device only a restricted space is available for the loudspeaker arrangement and its housing, generally occurs in known devices with a loudspeaker arrangement for playback of stereophonic audio signals accommodated in the device. This problem has an effect especially during playback of stereophonic audio signals and playback of bass tones, since, for their playback, because of physical reasons, a large loudspeaker spacing and large volume and therefore large dimensions of the loudspeaker arrangement and its housing are desirable in order to make possible playback of stereophonic signals and the bass tones that permit a pleasant sound experience.

It is therefore the task of the present invention to provide a loudspeaker arrangement in a device for playback of stereophonic audio signals that permits, even with restricted size of the device, a playback of stereophonic audio signals that are perceived as properly sounding.

This task is solved in the present invention by the features of claim 1.

It starts from a loudspeaker arrangement in a device for playback of stereophonic audio signals with a housing arranged in the device, a loudspeaker for bass signals and loudspeakers for mid-range and treble signals, in which crossover networks (in an active or passive version) separate the stereophonic audio signals for playback with the loudspeakers into bass signals and mid-range and treble signals, whose crossover networks have a crossover frequency higher than the cut-off frequency of the loudspeaker for bass signals.

The present invention has the advantage that a sound result with greater sound fullness can be achieved on this account, although the housing available for the loudspeaker arrangement has only limited spatial extent and limited volume.

Additional advantages of the present invention are apparent from the dependent claims as well as from the subsequent description of a variant according to the invention of a loudspeaker arrangement in a device for playback of stereophonic audio signals with reference to figures.

In the figures:

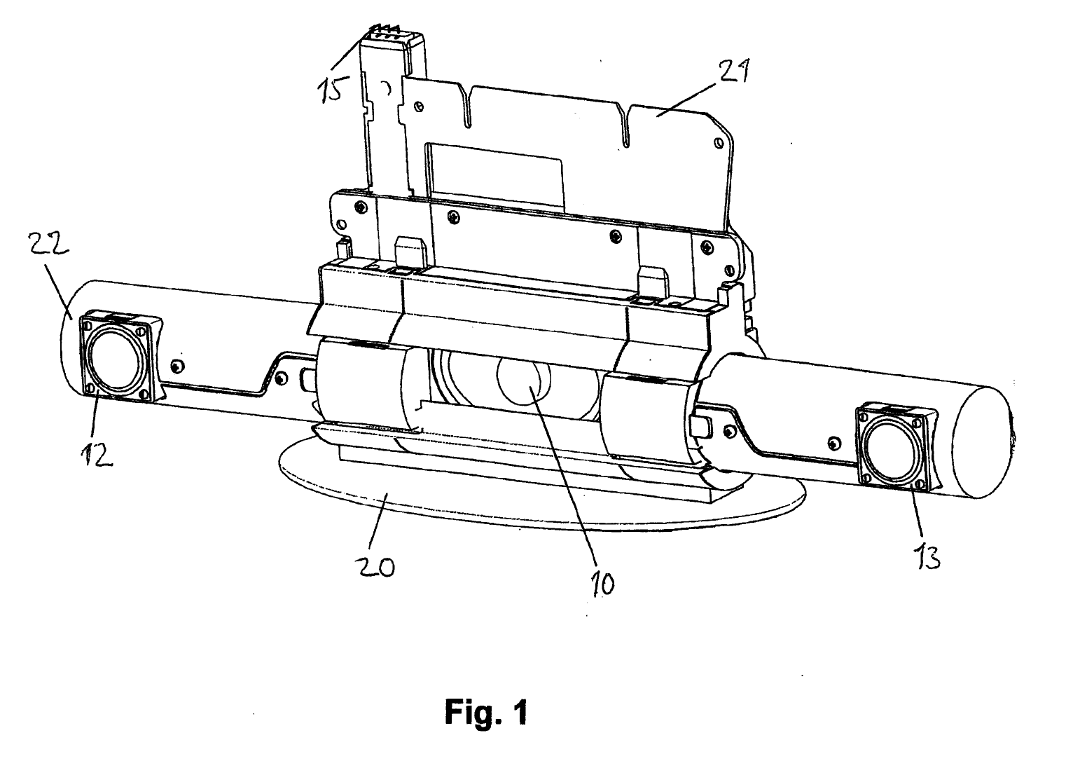

FIG. 1 shows a three-dimensional view of a loudspeaker arrangement in a device for playback of stereophonic audio signals,

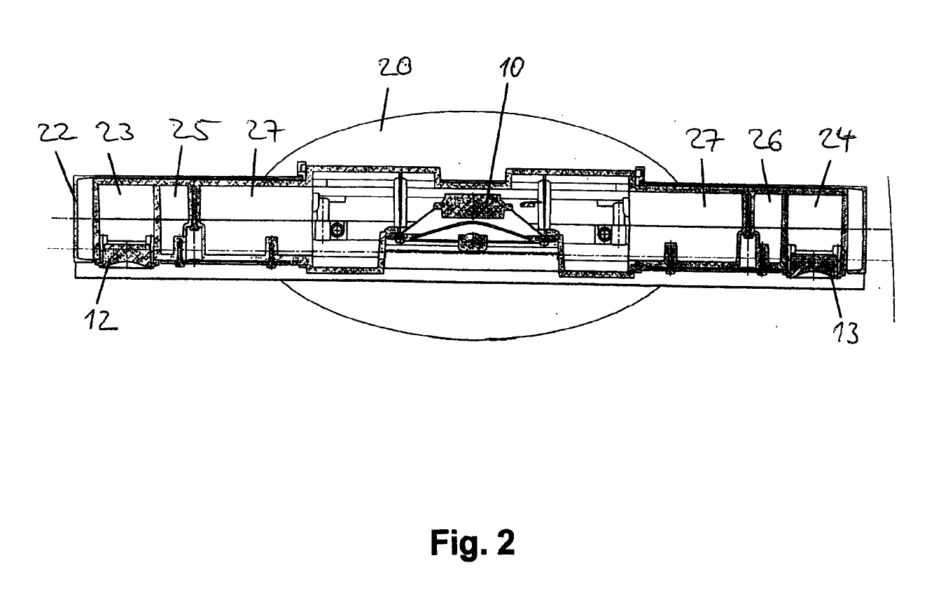

FIG. 2 shows a section through the device according to FIG. 1, and

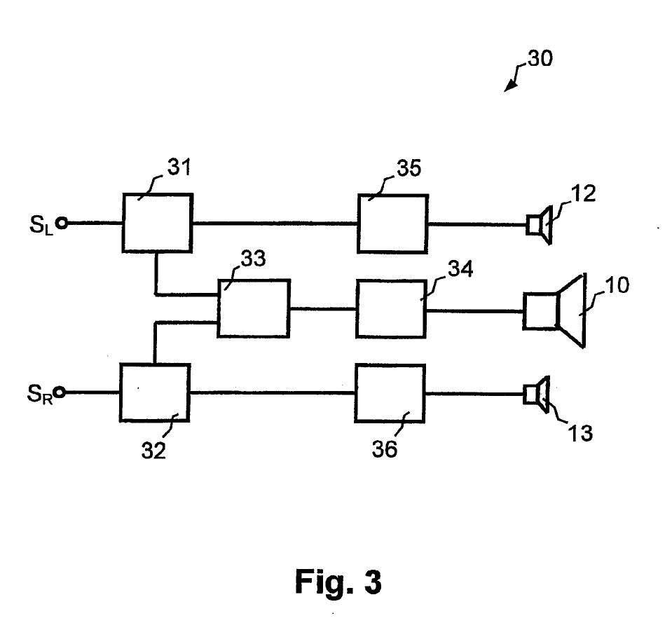

FIG. 3 shows a schematic illustration of a control of the loudspeaker arrangement according to FIG. 1.

To facilitate understanding of the present invention only the components that are significant in conjunction with the invention are shown in the figures. Equivalent components in different figures have the same reference numbers.

A three-dimensional depiction of a loudspeaker arrangement 10, 12, 13 in a device 20, 21, 22 in a device for playback of stereophonic audio signals is shown in FIG. 1.

The loudspeaker arrangement 10, 12, 13 comprises a loudspeaker 10 for playback of bass tones, for example, a so-called sub-woofer, as well as a loudspeaker 12 for playback of treble and mid-range tones of a left stereo channel and a loudspeaker 13 for playback of treble and mid-range tones of a right stereo channel.

The device 20, 21, 22 has a foot 20 for setup of the device, a fastening 21 to fasten additional components of the device, like electronic circuits, a display or casing, and a housing 22 to accommodate the loudspeaker arrangement 10, 12, 13.

Contacts 15 are provided for electrical connection of the loudspeaker arrangement 10, 12, 13.

FIG. 2 shows a section through the device 20, 21, 22 and through the housing 22 according to FIG. 1. Each of the loudspeakers 10, 12, 13 has its own partial housing 27, 23, 24, in which the partial housing 23, 24 of loudspeaker 12 for the left stereo channel and of the loudspeaker 13 for the right stereo channel are connected by means of chambers 25 and 26 to the partial housing 27 of loudspeaker 10 for the bass tones to avoid disturbances. The partial housings 23, 24, 27 and/or the chambers 25 and 26 can be acoustically dampened, for example, with appropriate fiber materials. A schematic illustration of a control 30 of the loudspeaker arrangement 10, 12, 13 according to FIG. 1 is shown in FIG. 3.

A signal S_{L} for the left stereo channel is applied to a crossover network 31. The treble and mid-range signal fractions of signal S_{L} go to an amplifier 35, which amplifies the signal fractions for playback with loudspeaker 12 for the left stereo channel. A signal S_{R} for the right stereo channel is applied to a crossover network 32. The treble and mid-range signal fractions of signal S_{R} go to an amplifier 36 that amplifies the signal fractions for playback with the loudspeaker 13 for the right stereo channel. The bass signal fractions of signals S_{L} and S_{R} are sent by the crossover networks 31 and 32 to a superposition circuit 33 that generates a bass signal that is amplified by an amplifier 34 for playback with loudspeaker 10. The crossover networks 31 and 32 can be formed in known fashion from capacitances and inductances. A resistance network can be used to implement the superposition circuit 33.

To achieve the desired sound properties it is proposed to select the crossover frequency of the crossover networks so that the crossover frequency is higher than the cut-off frequency of loudspeaker 10 for playback of the bass signal.

At a volume of partial housing 27 of loudspeaker 10 for the bass signal of 0.5-1.5 L and a power of the amplifier 34 of 5-16 W, as well as at a volume of the partial housing 25 and 26 of loudspeakers 12 and 13 for the mid-range and treble signal of about 0.04 L and at a power of the amplifiers 35 and 36 of 3-7 W, an appropriate crossover frequency lies at about 350 Hz. The spacing of the loudspeakers 12 and 13 for the mid-range and treble signals should then lie in the range from 150-500 mm.

The device having the loudspeaker arrangement can be a device for entertainment electronics, for example, a CD player, a television, etc. However, the device can also be a monitor for a computer or a computer. The stereophonic audio signals being played back in these cases come from the entertainment electronic device or computer.

1. Loudspeaker arrangement in a device for playback of stereophonic audio signals with a housing (22) arranged in the device, a loudspeaker (10) for bass signals and loudspeakers (12, 13) for mid-range and treble signals, in which crossover networks (31, 32) separate the stereophonic audio signals (S_{L}, S_{R}) for playback with loudspeakers (10, 12, 13) into a bass signal and mid-range and treble signals, characterized by the fact that the crossover networks (31, 32) have a crossover frequency higher than the cut-off frequency of loudspeaker (10) for bass signals.

2. Loudspeaker arrangement according to claim 1, wherein the crossover frequency of crossover networks (31, 32) is about 350 Hz.

3. Loudspeaker arrangement according to claim 1, wherein the loudspeakers (12, 13) for the mid-range and treble signals and the loudspeaker (10) for the bass signals have their own closed partial housing (23, 24, 27).

4. Loudspeaker arrangement according to claim 3, wherein the partial housing (23, 24, 27) of loudspeaker (12, 13) for the mid-range and treble signals and the loudspeaker (10) for bass signals are separated from each other by chambers (25, 26).

5. Loudspeaker arrangement according to claim 4, wherein at least one of the chambers (25, 26) and the partial housings (23, 24, 27) are acoustically dampened.

6. Loudspeaker arrangement according to claim 1, wherein the partial housing (27) of the loudspeaker (10) for the bass signals has a volume of 0.5-1.5 L.

7. Loudspeaker arrangement according to claim 1, wherein the partial housing (23, 24) of loudspeakers (12, 13) for the mid-range and treble signals have a volume of about 0.04 L each.

8. Loudspeaker arrangement according to claim 1, wherein the loudspeakers (12, 13) for the mid-range and treble signals have a distance from each other of 150-500 mm.

9. Loudspeaker arrangement according to claim 1, wherein the loudspeaker (10) for the bass signals is driven by an amplifier (35, 36) with a power of 5-16 watts W.

10. Loudspeaker arrangement according to claim 1, wherein the loudspeakers (12, 13) for the mid-range and treble signals are driven by amplifiers (35, 36) with a power of 3-7 watts each.

11. Loudspeaker arrangement according to claim 1, wherein the loudspeaker arrangement is a component of an entertainment electronics device.

12. Loudspeaker arrangement according to claim 1, wherein the loudspeaker arrangement is a component of a monitor or computer.
